(19) United States
(12) Patent Application Publication
(10) Pub. No.: US 2015/0207617 A1
(43) Pub. Date: Jul. 23, 2015

(54) RECEPTION CIRCUIT AND COMMUNICATION SYSTEM

(71) Applicant: Kabushiki Kaisha Toshiba, Minato-ku (JP)

(72) Inventor: Masayuki USUDA, Ota-ku (JP)

(73) Assignee: Kabushiki Kaisha Toshiba, Minato-ku (JP)

(21) Appl. No.: 14/256,493

(22) Filed: Apr. 18, 2014

Related U.S. Application Data
(60) Provisional application No. 61/930,186, filed on Jan. 22, 2014.

(51) Int. Cl. H04L 7/033; H03L 7/08

(52) U.S. Cl. CPC H04L 7/0331; H03L 7/08

(57) ABSTRACT

According to one embodiment, a reception circuit and a communication system include a multi-phase clock generator that generates a multi-phase clock based on a reception clock, an oversampling circuit that oversamples data according to the multi-phase clock, and a clock data recovery circuit that reproduces reception data and a synchronization clock synchronized with the reception data based on the data oversampled at the oversampling circuit.

### CROSS-REFERENCE TO RELATED APPLICATIONS

This application is based upon and claims the benefit of priority from Provisional Patent Application No. 61/930,186, filed on Jan. 22, 2014; the entire contents of which are incorporated herein by reference.

### FIELD

Embodiments described herein relate generally to reception circuits and communication systems.

### BACKGROUND

At a reception circuit, when the data rate becomes high, jitter and skews in data and clocks increase. Therefore, data cannot be latched in a stable period, which may lead to incorrect receipt of the data.

### BRIEF DESCRIPTION OF THE DRAWINGS

FIG. 1 is a schematic block diagram of a configuration of a communication system according to a first embodiment;

FIG. 2 is a timing chart of operations of the communication system according to the first embodiment;

FIG. 3 is a schematic block diagram of a configuration of a communication system according to a second embodiment;

FIG. 4 is a schematic block diagram of a configuration of a calibration circuit illustrated in FIG. 3;

FIG. 5 is a timing chart of a skew adjustment method for the calibration circuit illustrated in FIG. 4;

FIG. 6 is a schematic block diagram of a configuration of a communication system according to a third embodiment;

FIG. 7 is a schematic block diagram of a configuration of a communication system according to a fourth embodiment;

and

FIG. 8 is a schematic block diagram of a configuration of a memory system to which a communication system according to a fifth embodiment is applied.

### DETAILED DESCRIPTION

In general, according to one embodiment, a reception circuit and a communication system include a multi-phase clock generator, an oversampling circuit, and a clock data recovery circuit. The multi-phase clock generator generates a multi-phase clock based on a received clock. The oversampling circuit oversamples data according to the multi-phase clock. The clock data recovery circuit reproduces reception data and a synchronization clock synchronized with the reception data, based on the data oversampled at the oversampling circuit.

Exemplary embodiments of a reception circuit and a communication system will be explained below in detail with reference to the accompanying drawings. The present invention is not limited to the following embodiments. (First embodiment)

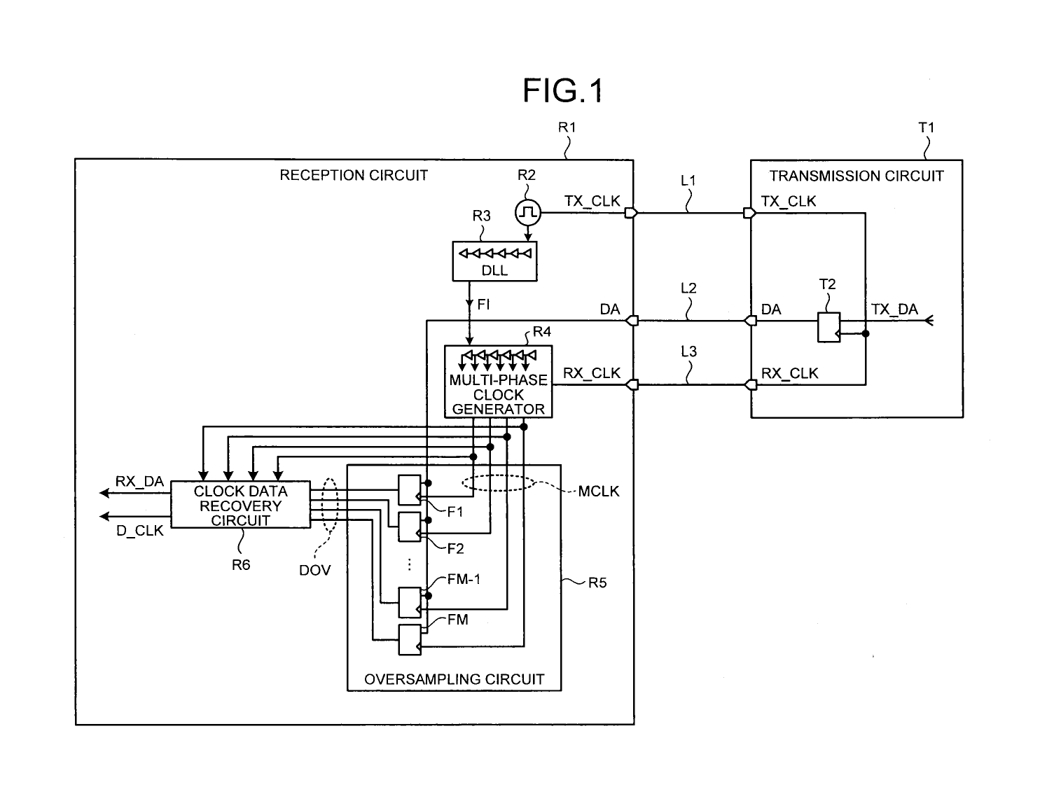

FIG. 1 is a schematic block diagram of a configuration of a communication system according to a first embodiment.

Referring to FIG. 1, provided in the communication system are a reception circuit R1 and a transmission circuit T1. In this case, the reception circuit R1 and the transmission circuit T1 are connected together via signal lines L1 to L3. The signal line L1 is capable of transmitting a transmission clock TX CLK from the reception circuit R1 to the transmission circuit T1. The signal line L2 is capable of transferring data DA from the transmission circuit T1 to the reception circuit R1. The signal line L3 is capable of transmitting a reception clock RX CLK from the transmission circuit T1 to the reception circuit R1. The reception circuit R1 can be used as a reception interface included in a semiconductor integrated circuit, and the transmission circuit T1 can be used as a transmission interface included in a semiconductor integrated circuit.

Provided in the reception circuit R1 are a clock generator R2, a delay locked loop (DLL) circuit R3, a multi-phase clock generator R4, an oversampling circuit R5, and a clock data recovery circuit R6. The clock generator R2 is capable of generating a reference clock. The delay locked loop (DLL) circuit R3 is locked at a frequency of the reference clock generated at the clock generator R2 and is capable of outputting frequency information F1 on the frequency to the multi-phase clock generator R4. The multi-phase clock generator R4 is capable of generating a multi-phase clock MCLK based on the reception clock RX_CLK. In this case, when there exists multi-phase clock MCLK for M (M is an integer of two or more) phases, the multi-phase clock generator R4 can be provided with delay circuits for M stages. The delay circuits can be configured using replicas of a delay circuit in the DLL circuit R3. The oversampling circuit R5 is capable of oversampling data DA according to the multi-phase clock MCLK. In this case, the oversampling circuit R5 is provided with M latch circuits F1 to FM corresponding to the phases of the multi-phase clock MCLK. The latch circuits F1 to FM are capable of latching the data DA at risings of the phases of the multi-phase clock MCLK. The clock data recovery circuit R6 is capable of reproducing reception data RX_DA and a synchronization clock D_CLK synchronized with the reception data RX_DA, based on oversampling data DOV output from the oversampling circuit R5.

The transmission circuit T1 is provided with a latch circuit T2. The latch circuit T2 is capable of latching transmission data TX_DA in synchronization with both rising and falling edges of the transmission clock TX_CLK, and outputting the same as data DA.

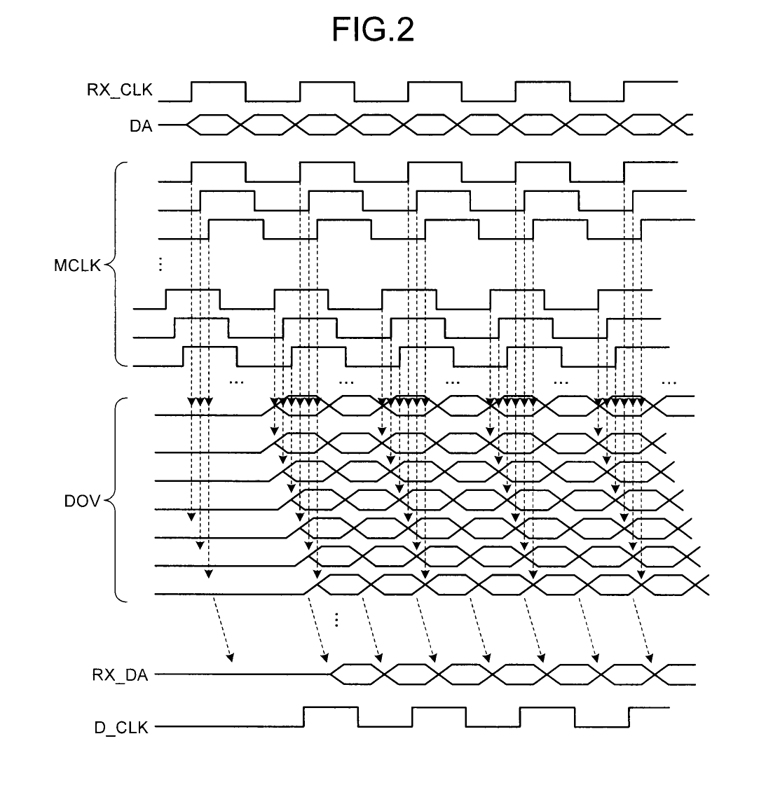

FIG. 2 is a timing chart of operations of the communication system according to the first embodiment.

Referring to FIG. 2, the reference clock generated at the clock generator R2 is transmitted as transmission clock TX_CLK to the transmission circuit T1 via the signal line L1. Then, at the latch circuit T2, the transmission data TX_DA is latched in synchronization with the transmission clock TX_CLK, and transmitted as data DA to the reception circuit R1 via the signal line L2. The transmission clock TX_CLK transmitted to the transmission circuit T1 is returned as reception clock RX_CLK to the reception circuit R1 via the signal line L3.

In addition, the reference clock generated at the clock generator R2 is input into the DLL circuit R3. Then, the DLL circuit R3 is locked at the frequency of the reference clock, and the frequency information F1 on the frequency is input into the multi-phase clock generator R4. Then, the multi-phase clock generator R4 is locked at the frequency of the reference clock of the clock generator R2, and the multi-phase clock MCLK is generated based on the reception clock RX_CLK. Then, the phases of the multi-phase clock MCLK are input into the latch circuits F1 to FM, and the data DA is latched in synchronization with the phases of the multi-phase clock MCLK, and thus the oversampling data DOV is generated and output to the clock data recovery circuit R6. Then, at the clock data recovery circuit R6, the reception data RX_DA and the synchronization clock D_CLK are reproduced based on the oversampling data DOV. At the reproduction of the synchronization clock D_CLK, it is possible to detect a timing of logical inversion from the oversampling data DOV and select, from the multi-phase clock MCLK, a clock synchronized with the timing. At the reproduction of the reception data RX_DA, it is possible to select, from the oversampling data DOV, data retrieved on a clock with a predetermined phase difference (for example, 90°) from the synchronization clock D_CLK.

In this case, by reproducing the reception data RX_DA and the synchronization clock D_CLK based on the oversampling data DOV, it is possible to reduce jitter and skews in data and clocks, and receive the data correctly even when the data rate becomes high.

In addition, by generating the multi-phase clock MCLK based on the reception clock RX_CLK, it is possible to prevent the reception data RX_DA from being output when the reception clock RX_CLK is not received. Accordingly, it is possible to receive the data DA from the beginning and recognize the beginning of the data DA at the reception circuit R1 side.

### Second Embodiment

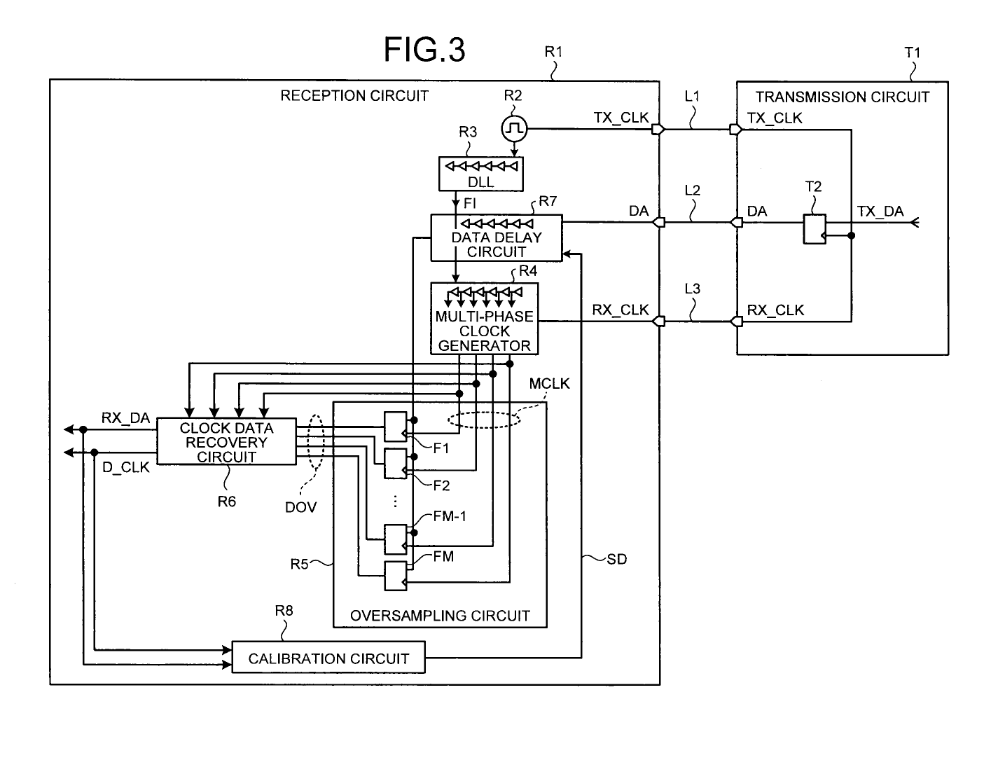

FIG. 3 is a schematic block diagram of a configuration of a communication system according to a second embodiment.

Referring to FIG. 3, in this communication system, a data delay circuit R7 and a calibration circuit R8 are added to the configuration of FIG. 1. The data delay circuit R7 is capable of adjusting the amount of delay of the data DA input into the oversampling circuit R5. The calibration circuit R8 is capable of setting the amount of delay of the data DA such that the reception data RX DA can be correctly reproduced.

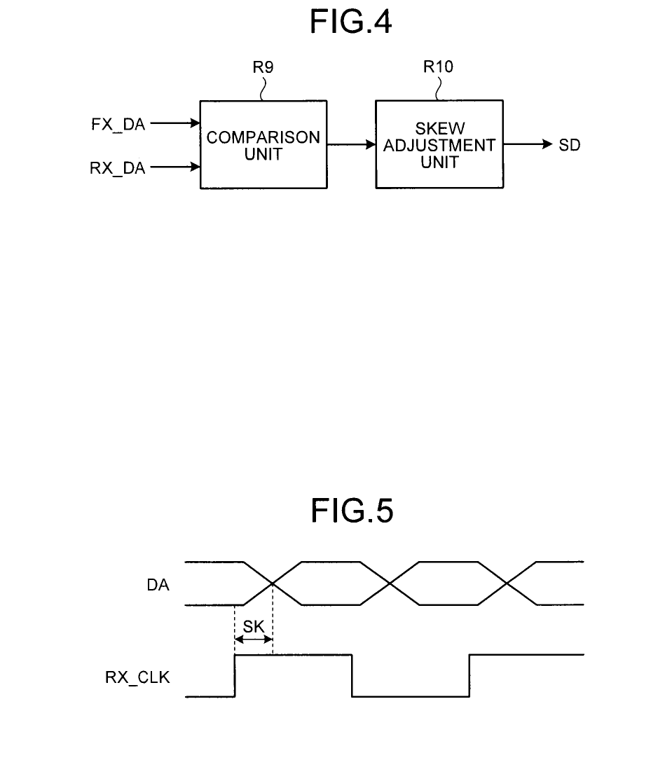

FIG. 4 is a schematic block diagram of a configuration of a calibration circuit illustrated in FIG. 3, and FIG. 5 is a timing chart of a skew adjustment method for the calibration circuit illustrated in FIG. 4.

Referring to FIG. 4, the calibration circuit R8 is provided with a comparison unit R9 and a skew adjustment unit R10. The comparison unit R9 is capable of comparing the reception data RX_DA with correct data FX_DA. The correct data FX_DA is capable of being held in advance in the reception circuit R1. The skew adjustment unit R10 is capable of adjusting a skew SK between the data DA and the reception clock RX_CLK such that the reception data RX_DA matches the correct data FX_DA.

In addition, the reception circuit R1 is capable of setting a calibration period prior to a reception period in which the data DA is received. In the calibration period, the correct data FX_DA is transmitted as transmission data TX_DA from the transmission circuit T1 to the reception circuit R1. Then, at the reception circuit R1, the reception data RX_DA reproduced at that time is transmitted to the comparison unit R9 for comparison with the correct data FX_DA. Then, at the skew adjustment unit R10, a delay control signal SD is generated based on the result of the comparison at the comparison unit R9, and is transmitted to the data delay circuit R7. Then, at the data delay circuit R7, the amount of delay of the data DA is adjusted based on the delay control signal SD, and thus the skew SK is adjusted and input into the oversampling circuit R5.

At that time, at the skew adjustment unit R10, the skew SK is repeatedly adjusted until the reception data RX DA matches the correct data FX_DA, thereby to improve the correction rate of the reception data RX_DA.

### Third Embodiment

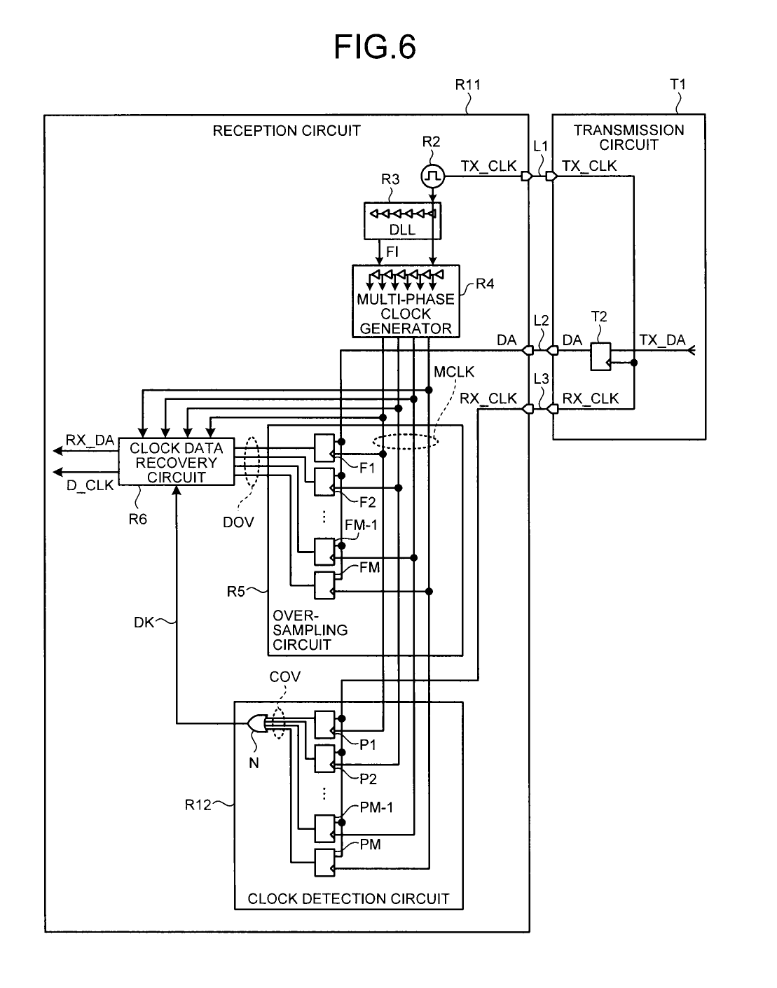

FIG. 6 is a schematic block diagram of a configuration of a communication system according to a third embodiment.

Referring to FIG. 6, in this communication system, a reception circuit R11 is provided instead of the reception circuit R1 of FIG. 1. At the reception circuit R11, a clock detection circuit R12 is added to the reception circuit R1 of FIG. 1. The clock detection circuit R12 is capable of detecting the reception clock RX_CLK by sampling the reception clock RX_CLK according to the multi-phase clock MCLK. In this case, the clock detection circuit R12 is provided with M latch circuits P1 to PM and an OR circuit N corresponding to the phases of the multi-phase clock MCLK. The latch circuits P1 to PM are capable of latching the reception clock RX_CLK at risings of the phases of the multi-phase clock MCLK. The OR circuit N is capable of taking the logical sum of outputs from the latch circuits P1 to PM.

Then, the phases of the multi-phase clock MCLK are input into the latch circuits P1 to PM, and the reception clock RX_CLK is latched in synchronization with the phases of the multi-phase clock MCLK, and thus an oversampling clock COV is generated and input into the OR circuit N. Then, at the OR circuit N, the logical sum of the oversampling clock COV is taken, and thus a clock detection signal DK is generated and output to the clock data recovery circuit R6. Then, at the clock data recovery circuit R6, the beginning of the data DA is recognized based on the clock detection signal DK.

In this case, by recognizing the beginning of the data DA based on the oversampling clock COV, it is possible to improve the accuracy of recognition of the beginning of the data DA.

### Fourth Embodiment

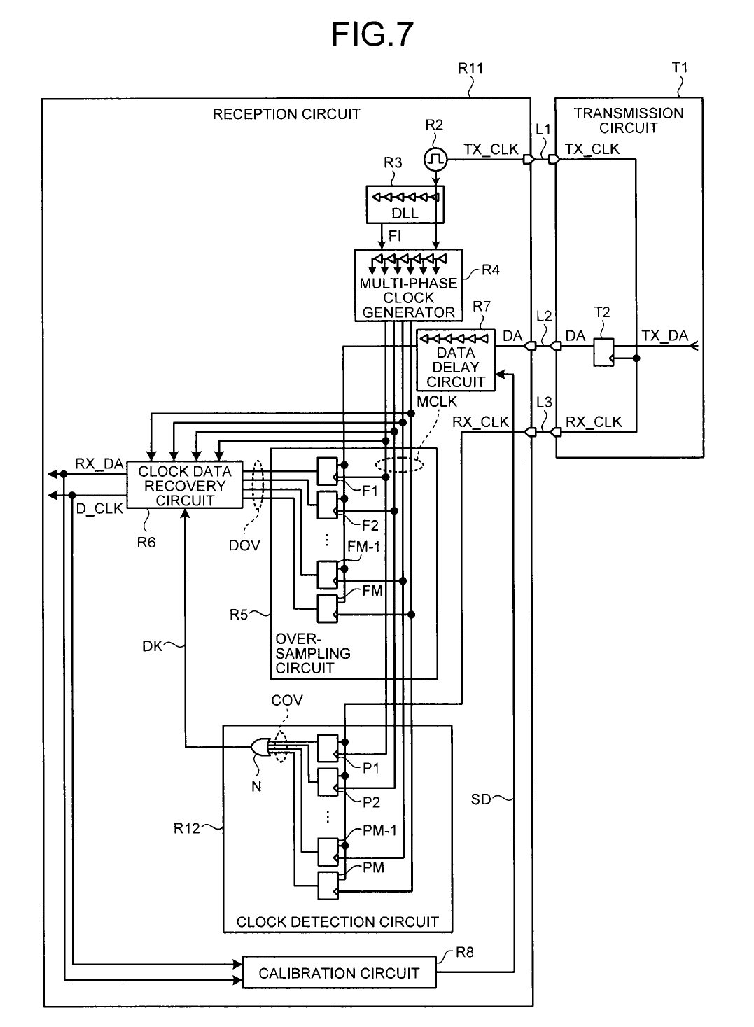

FIG. 7 is a schematic block diagram of a configuration of a communication system according to a fourth embodiment.

Referring to FIG. 7, in this communication system, a data delay circuit R7 and a calibration circuit R8 are added to the configuration of FIG. 6.

In addition, the reception circuit R11 is capable of setting a calibration period prior to a reception period in which the data DA is received. In the calibration period, the correct data FX_DA is transmitted as transmission data TX_DA from the transmission circuit T1 to the reception circuit R11. Then, at the reception circuit R11, the reception data RX_DA reproduced at that time is transmitted to the comparison unit R9 for comparison with the correct data FX_DA. Then, at the skew adjustment unit R10, the skew SK is repeatedly adjusted until the reception data RX_DA matches the correct data FX_DA.

Accordingly, it is possible to recognize the beginning of the data DA based on the oversampling clock COV, improve the accuracy of recognition of the beginning of the data DA, and improve the correction rate of the reception data RX_DA.

### Fifth Embodiment

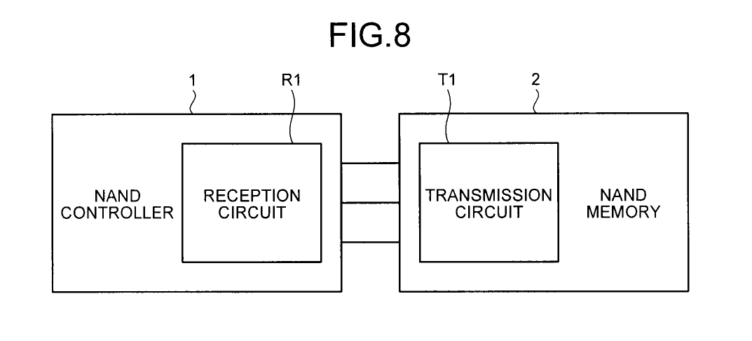

FIG. 8 is a schematic block diagram of a configuration of a memory system to which a communication system according to a fifth embodiment is applied. In the example of FIG. 8, an NAND memory is used in a memory system.

Referring to FIG. 8, the memory system is provided with an NAND controller 1 and an NAND memory 2. The NAND controller 1 is capable of performing drive control on the NAND memory 2. The drive control on the NAND memory 2 includes read/write control, block selection, error correction, wear leveling, and the like on the NAND memory 2. The NAND controller 1 is provided with a reception circuit R1, and the NAND memory 2 is provided with a transmission circuit T1. The reception circuit R1 and the transmission circuit T1 may be configured as illustrated in FIG. 1, or may be configured as illustrated in FIG. 3. Instead of the reception circuit R1 and the transmission circuit T1, the reception circuit R11 and the transmission circuit T1 illustrated in FIG. 6 or 7 may be provided. The NAND controller 1 and the NAND memory 2 may be included in a memory card or included in eMMC™ or the like.

In this case, by including the reception circuit R1 and the transmission circuit T1 in the NAND controller 1 and the NAND memory 2, respectively, even when the data rate becomes high, it is possible to receive data correctly at the NAND controller 1 side and recognize the beginning of the data transmitted from the NAND memory 2 side.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A reception circuit, comprising:
a multi-phase clock generator that generates a multi-phase clock based on a reception clock;
an oversampling circuit that oversamples data according to the multi-phase clock; and
a clock data recovery circuit that reproduces reception data and a synchronization clock synchronized with the reception data, based on the data oversampled at the oversampling circuit.

2. The reception circuit according to claim 1, comprising:
a clock generator that generates a reference clock; and
a DLL circuit that is locked at a frequency of the reference clock and outputs frequency information on the frequency to the multi-phase clock generator.

3. The reception circuit according to claim 2, wherein the multi-phase clock generator is locked at a frequency of the reference clock and delays the reception clock to generate the multi-phase clock.

4. The reception circuit according to claim 3, wherein the multi-phase clock generator is configured using a replica of a delay circuit in the DLL circuit.

5. The reception circuit according to claim 1, wherein the reference clock is transmitted as a transmission clock, and the transmission clock is received as the reception clock.

6. The reception circuit according to claim 1, comprising:
a data delay circuit that adjusts an amount of delay of the data input into the oversampling circuit; and
a calibration circuit that sets the amount of delay of the data such that the reception data is correctly reproduced.

7. The reception circuit according to claim 6, wherein the calibration circuit includes:
a comparison unit that compares the reception data with correct data; and
a skew adjustment unit that adjusts a skew between the data and the reception clock such that the reception data matches the correct data.

8. The reception circuit according to claim 1, comprising a clock detection circuit that detects the reception clock by sampling the reception clock according to the multi-phase clock.

9. The reception circuit according to claim 8, wherein the clock data recovery circuit identifies beginning data based on results of detection of the reception clock by the clock detection circuit.

10. The reception circuit according to claim 1, wherein
the reception circuit is included in an NAND controller, and
the data is transmission data transmitted from the NAND memory.

11. A communication system, comprising a reception circuit and a transmission circuit, wherein
the reception circuit includes:
a multi-phase clock generator that generates a multi-phase clock based on the reception clock received from the transmission circuit;
an oversampling circuit that oversamples data according to the multi-phase clock; and
a clock data recovery circuit that reproduces reception data and a synchronization clock synchronized with the reception data, based on the data oversampled at the oversampling circuit, wherein
the transmission circuit transmits a transmission clock transmitted from the reception circuit as the reception clock to the reception circuit, and transmits the transmission data as the data to the reception circuit according to the transmission clock.

12. The communication system according to claim 11, wherein
the reception circuit includes:
a clock generator that generates a reference clock; and
a DLL circuit that is locked at a frequency of the reference clock and outputs frequency information on the frequency to the multi-phase clock generator.

13. The communication system according to claim 12, wherein the multi-phase clock generator is locked at a frequency of the reference clock and delays the reception clock to generate the multi-phase clock.

14. The communication system according to claim 13, wherein the multi-phase clock generator is configured using a replica of a delay circuit of the DLL circuit.

15. The communication system according to claim 11, comprising:
a first signal line that transfers the transmission clock from the reception circuit to the transmission circuit;
a second signal line that transfers the data from the transmission circuit to the reception circuit; and
a third signal line that transfers the reception clock from the transmission circuit to the reception circuit.

16. The communication system according to claim 11, wherein the reception circuit includes:
a data delay circuit that adjusts an amount of delay of the data input into the oversampling circuit; and
a calibration circuit that sets the amount of delay of the data such that the reception data is correctly reproduced.

17. The communication system according to claim 16, wherein the calibration circuit includes:
a comparison unit that compares the reception data with correct data; and
a skew adjustment unit that adjusts a skew between the data and the reception clock such that the reception data matches the correct data.

18. The communication system according to claim 11, wherein the reception circuit samples the reception clock according to the multi-phase clock to detect the reception clock.

19. The communication system according to claim 18, wherein the clock data recovery circuit identifies beginning data based on results of detection of the reception clock by the clock detection circuit.

20. The communication system according to claim 11, wherein the reception circuit is included in an NAND controller and the transmission circuit is included in an NAND memory.
